(19) United States
(12) Patent Application Publication
(10) Pub. No.: US 2007/0202646 A1
(43) Pub. Date: Aug. 30, 2007

(54) Method for forming a flash memory floating gate

(75) Inventor: Shih-Der Tseng, Hsin-Chu City (TW)

Correspondence Address: TUNG & ASSOCIATES;Suite 120, 838 W. Long Lake Road, Bloomfield Hills, MI, 48302, US

(73) Assignee: Taiwan Semiconductor Manufacturing Co., Ltd.

(21) Appl. No.: 11/363,861

(22) Filed: Feb. 27, 2006

(51) Int. Cl. H01L 21/336

(52) U.S. Cl. 438/257

(57) ABSTRACT

A flash memory cell with an improved floating gate electrode and method for forming the same, the method including providing a semiconductor substrate active area electrically isolated by STI structures; forming a gate dielectric over the semiconductors substrate; forming a nitride mask layer on the gate dielectric and forming an opening in the nitride mask layer defining a floating gate electrode; backfilling the opening with polysilicon to form the floating gate electrode; and, isotropically etching the upper portion of the floating gate electrode to form a recessed area.

### FIELD OF THE INVENTION

The invention generally relates to processing methods for forming semiconductor device structures, and more particularly to a method for forming a flash memory device including an improved floating gate electrode.

### BACKGROUND OF THE INVENTION

In flash devices, the level of voltage in the floating gate electrode and tunneling current through respective insulating layers is frequently dependent on insulating layer profiles and gate electrode profiles. For example, Fowler-Nordheim tunneling has an exponential field dependence and the electric field produced at insulator/electrode interfaces can be strongly affected by the respective profiles.

For example, the polysilicon spacer (electrode) profile can affect the series resistance and hence the electrical stability of the control gate, for example, including altering hot electron injection processes or Fowler-Nordheim tunneling processes which adversely affect the stability of the control gate thereby adversely affecting the reliability of write and erase operations, both processes essential to the reliable operation of flash memory devices. For example, the electric field strength present at a polysilicon electrode/gate oxide (tunnel oxide) interface, determines the desired flow of current in response to applied voltages to accomplish write and erase operations.

In the formation of polysilicon word and source line electrodes in conjunction with a split gate FET device, for example employing a self-aligned polysilicon wordline electrode in a split gate FET configuration, a consistent and predictable profile of the polysilicon floating gate structure is critical to proper electrical functioning of the device. As design rules have decreased to below about 0.25 micron technology, achieving acceptable profiles of the polysilicon gate floating gate structure has become increasingly difficult.

One particular problem in forming polysilicon floating gate electrodes is the formation of an oxidized birds beak in the upper portion of the polysilicon floating gate prior to formation of the polysilicon wordline. For example referring to FIG. 1 is shown a typical silicon dioxide birds beak 16 formed in the upper portion of polysilicon floating gate 14 overlying gate oxide portion 12A formed on semiconductor substrate 12. The silicon dioxide birds beak 16 is typically formed in an upper portion of a masked polysilicon layer by a thermal oxidation growth process prior to etching the polysilicon layer to form the polysilicon floating gate 14. According to a thermal oxide growth process, a bird's beak shape 16 is formed in an exposed upper portion of the polysilicon layer. Following forming the floating gate electrode 14 including oxidized bird's beak portion 16, an insulator layer 12B is then formed on the floating gate electrode 14 followed by formation of polysilicon wordline 18.

One problem with the prior art process is the difficulty in controlling the shape of the birds beak 16 and therefore the unoxidized polysilicon portion of the polysilicon floating gate 14. The prior art process has been found to result in degraded device performance as device sizes decrease including degraded erase operations.

here is therefore a need in the device processing art to develop improved device structures and processes for forming the same to improve device performance and reliability as well as improving the ability to scale down memory cell size.

It is therefore an object of the invention to provide improved device structures and processes for forming the same to improve device performance and reliability as well as improving the ability to scale down memory cell size, while overcoming other deficiencies and shortcomings of the prior art.

### SUMMARY OF THE INVENTION

To achieve the foregoing and other objects, and in accordance with the purposes of the present invention as embodied and broadly described herein, the present invention provides a flash memory cell with an improved floating gate electrode and method for forming the same.

In a first embodiment, the method includes providing a semiconductor substrate active area electrically isolated by STI structures; forming a gate dielectric over the semiconductors substrate; forming a nitride mask layer on the gate dielectric and forming an opening in the nitride mask layer defining a floating gate electrode; backfilling the opening with polysilicon to form the floating gate electrode; and, dry etching the upper portion of the floating gate electrode to form a recessed area.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIG. 1 is a cross sectional schematic view of a portion of an exemplary flash memory device according to the prior art.

FIGS. 2A-2G are cross sectional schematic views of a portion of an exemplary flash memory cell at stages in manufacture according to an embodiment of the present invention.

FIG. 3 is a process flow diagram including several embodiments of the present invention.

### DETAILED DESCRIPTION OF THE PREFERRED EMBODIMENTS

Although the method of the present invention is explained with reference to an exemplary embodiment including the formation of a split gate flash memory device, it will be appreciated that the method of the present invention may be advantageously used in the formation of any polysilicon electrode structure where the profile of the polysilicon gate electrode may be advantageously more precisely controlled to improve device operation including write and/or erase operations.

For example, referring back to FIG. 1, it has been found that a poorly defined oxide birds beak portion 16 overlying polysilicon portion 14 detrimentally affects the thickness uniformity of the overlying insulator 12B, thereby causing detrimental effects in erase operations. For example, it has been found that the thickness nonuniformity detrimentally affects charge carrier e.g., electron tunneling behavior and therefore degrades device reliability, performance, and yield. In addition, as split gate flash memory cell sizes decrease, the oxide/polysilicon interface definition according to prior art processes is increasingly limited, thereby limiting the ability to reduce and control flash memory cell size. It is among the foregoing shortcomings that the present invention is intended to overcome.

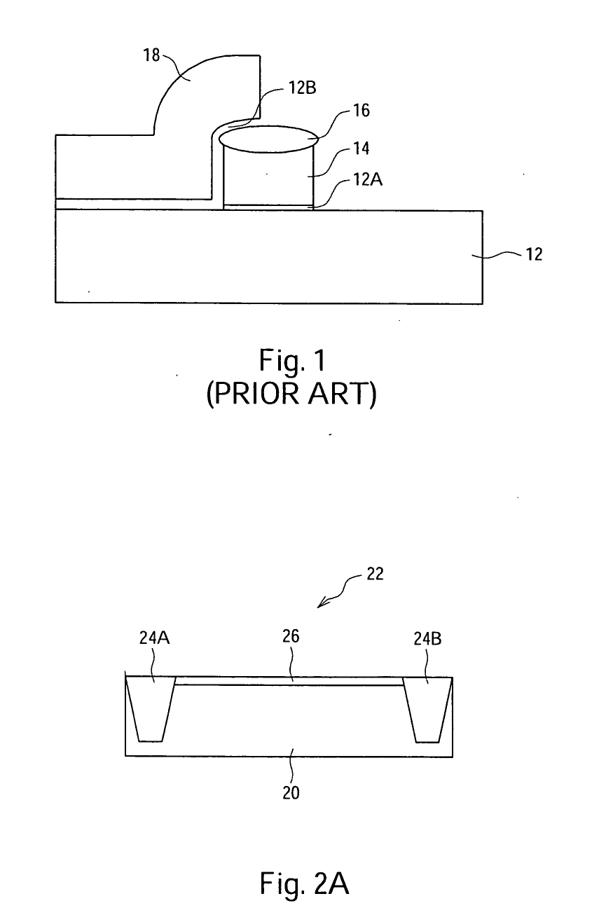

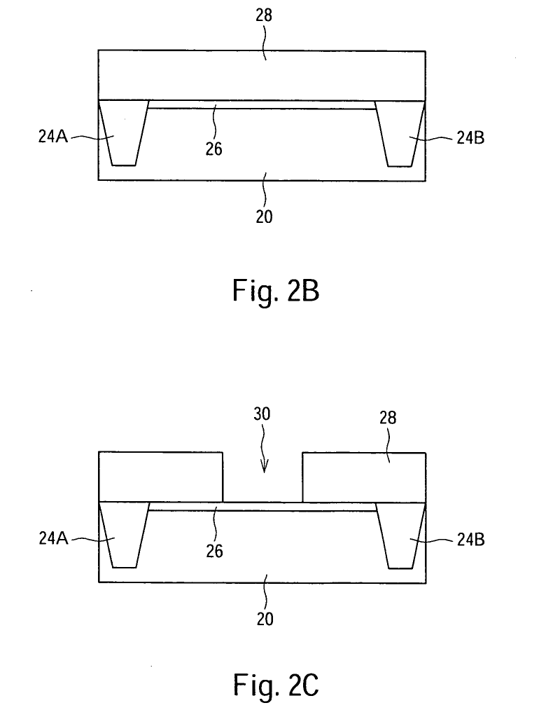

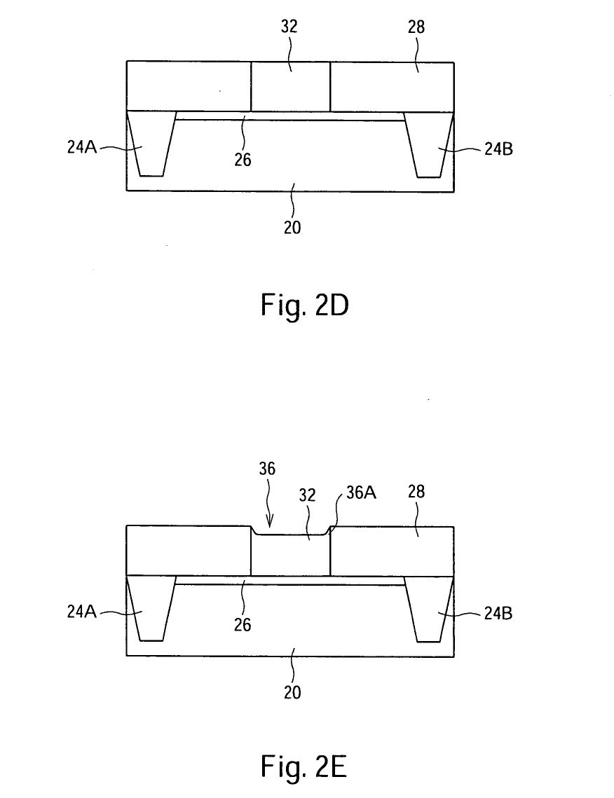

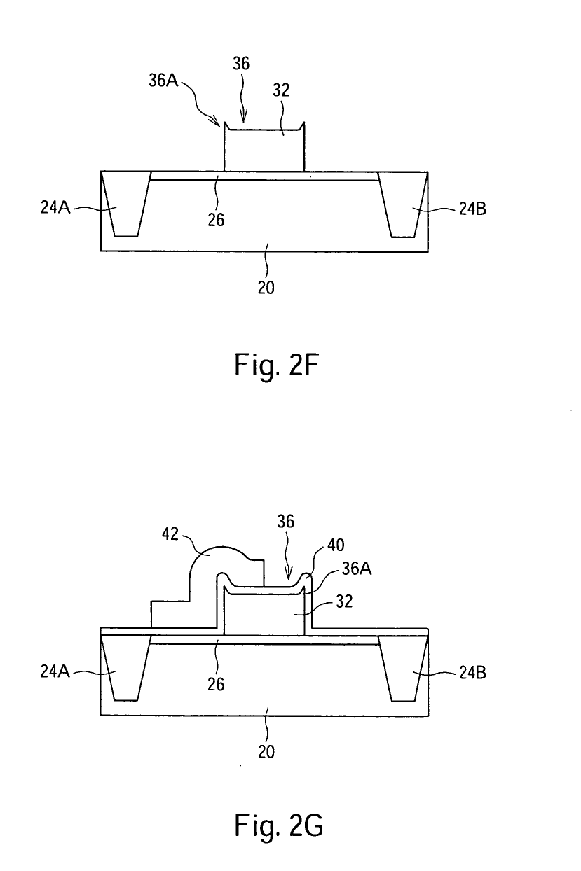

Shown in FIG. 2A is a semiconductor substrate, 20, including an active area of a memory cell 22, having shallow trench isolation (STI) structures 24A and 24B formed on either side of the active area by conventional methods including being backfilled with silicon oxide. The semiconductor substrate 20 for example, may include, but is not limited to, silicon, silicon on insulator (SOI), stacked SOI (SSOI), stacked SiGe on insulator (S—SiGeOI), SiGeOI, and GeOI, and combinations thereof.

Still referring to FIG. 2A, a gate dielectric layer 26 is formed over the semiconductors substrate 20. For example the gate dielectric is preferably, but not limited to silicon dioxide formed by conventional chemical, thermal, or CVD deposition methods, more preferably a thermal growth method, having a thickness of from about 50 Angstroms to about 100 Angstroms.

Referring to FIG. 2B, a mask layer 28, preferably formed of silicon nitride (e.g., Si₃N₄) and/or silicon oxynitride, more preferably silicon nitride, is blanket deposited over the gate dielectric layer 26. The silicon nitride layer 28 may be deposited by conventional CVD methods including PECVD, but is most preferably deposited by an APCVD or LPCVD method to enhance a dry etching selectivity in a subsequent dry etching process. The nitride mask layer 28 is preferably formed at a thickness of about 500 Angstroms to about 1500, Angstroms in thickness.

Referring to FIG. 2C, a conventional photolithographic patterning process is carried out by patterning a photoresist layer (not shown) overlying the silicon nitride layer 28 followed by dry etching to form an opening 30 corresponding to a desired floating gate electrode width through the silicon nitride layer 28 thickness to expose the underlying gate dielectric 26.

Referring to FIG. 2D, the opening 30 is then backfilled with polysilicon layer 32 by a conventional CVD polysilicon deposition process, preferably an LPCVD process, followed by a polysilicon CMP process to remove excess deposited polysilicon over the opening level to define a floating gate electrode polysilicon layer portion e.g., 32. It will be appreciated that the polysilicon may be doped, undoped, amorphous, or crystalline.

Referring to FIG. 2E, following formation of polysilicon layer (floating gate electrode) 34, a dry etching process is carried out to etch the top portion of the polysilicon layer 34 to form a recessed area 36 preferably having inwardly sloping sidewalls e.g., 36A. For example the sidewalls in the recessed area 36 slope inwardly from the floating gate electrode outer edges at an upper portion toward a bottom portion. The bottom portion of the recessed area 36 may be substantially level with the substrate or the sloped sidewalls and the bottom portion may form a concave shaped surface. For example a dry etching process including fluorocarbon etching chemistry with a carbon to fluorine ratio of greater than about 2.5, such as hexafluoroethane (C₂F₆) and argon, with optional addition of oxygen (O₂) and/or nitrogen (N₂) to control an etch rate is carried out to form the recessed area 36. For example, a polymer passivation layer is formed in-situ during the dry etching process on the sidewall portions of the etched recessed area 36 allowing a desired sidewall slope to form the recessed area 36. For example, the etching process may be carried out at temperatures at about 30° C. or lower to enhance a polymer passivation layer formation rate relative to an etching rate to control the desired slope of the sidewalls.

Referring to FIG. 2F, the silicon nitride layer 28 is then removed by a conventional wet etching process using H₃PO₄ to form floating gate electrode portion 32.

Referring to FIG. 2G, a dielectric insulating layer 40, for example CVD TEOS silicon oxide is blanket deposited over the floating gate electrode 32 to form an interpoly spacer layer. It will be appreciated that the interpoly spacer layer 40 may include a nitride/oxide layer such as an ONO (e.g., oxide-nitride-oxide) layer formed by sequential oxide and nitride CVD depositions, or plasma nitridation processes carried out following oxide layer deposition. In addition, the interpoly spacer layer 40 may include first carrying out a plasma nitridation process to form thin nitride passivation portion of a few Angstroms e.g., 5 to 10 Angstroms in thickness to line the outer portion of the floating gate electrode 32 prior to formation of major TEOS oxide or ONO portion of the interpoly spacer layer 40. Conventional processes are then carried out to form wordline 42, for example formed of doped or undoped polysilicon, formed by conventional blanket deposition and photolithographic patterning and etching processes, to form a wordline portion on the interpoly spacer layer 40 adjacent the floating gate electrode 32 outer sidewalls and overlying a portion of the upper portion of the floating gate electrode.

Advantageously, the floating gate electrode formed according to the method of the present invention, allows mare precise and accurate formation of the shape (profile) of the floating gate electrode and consequently a more uniform and well defined interpoly oxide spacer separating the word line and the floating gate electrode. For example, the present invention overcomes shortcomings of prior art processes using a polysilicon oxidation to shape the upper portion of the floating gate electrode, where silicon oxide growth including gate electrode dimension expansion results in a non-uniform shape of the floating gate electrode, thereby resulting in a non-uniform interpoly spacer thickness between the floating gate electrode and the word line.

As a result, according to the present invention, electron tunneling performance between the floating gate electrode and the word line across the interpoly spacer in response to an applied Voltage, for example to accomplish an erase operation, is improved. In addition, by having a well defined floating gate electrode, a flash memory cell size may be more easily scaled down in size, due to the improved reliability of formation of a desired interpoly spacer thickness to accomplish charge carrier e.g., electron tunneling.

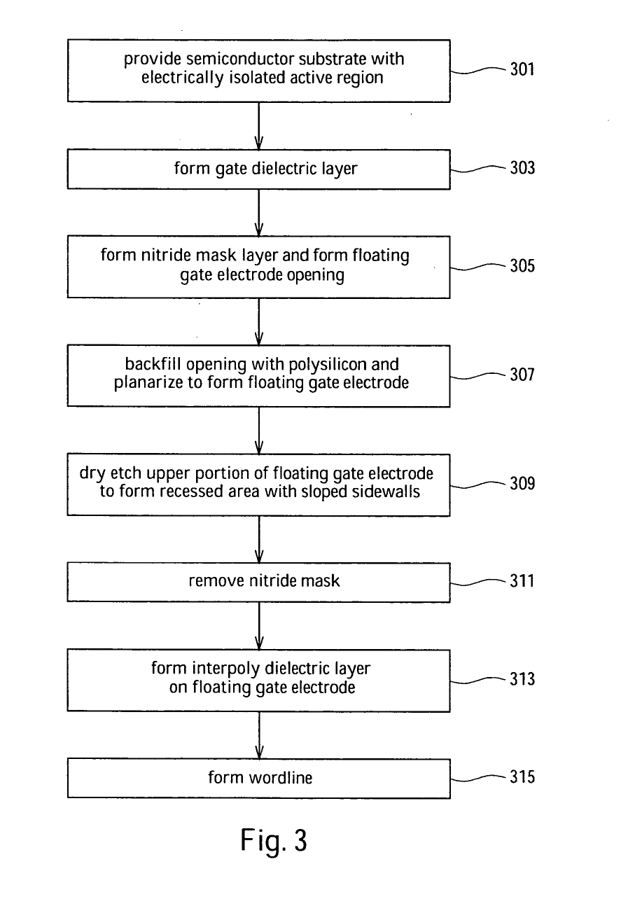

Referring to FIG. 3 is a process follow diagram including several embodiments of the present invention. In process 301, a semiconductor substrate is provided with an active region electrically isolated by STI structures. In process 303, a gate dielectric layer is formed over the semiconductor substrate surface. In process 305, a nitride mask layer is formed over the gate dielectric layer and a floating gate electrode opening is formed. In process 307, the floating gate electrode opening is backfilled with polysilicon and planarized to form a gate electrode portion. In process 309, the upper portion of the floating gate electrode is dry etched to form a recessed area with sloped sidewalls. In process 311, the nitride mask layer is removed to leave a floating gate electrode portion. In process 313 an interpoly dielectric spacer is formed on the floating gate electrode. In process 315, a wordline is formed on the interpoly dielectric spacer.

The preferred embodiments, aspects, and features of the invention having been described, it will be apparent to those skilled in the second art that numerous variations, modifications, and substitutions may be made without departing from the spirit of the invention as disclosed and further claimed below.

What is claimed is:

1. A method for forming a flash memory cell with an improved floating gate electrode comprising the steps of:
providing a semiconductor substrate active area electrically isolated by STI structures;
forming a gate dielectric over the semiconductors substrate;
forming a nitride mask layer on the gate dielectric and forming an opening in the nitride mask layer defining a floating gate electrode;
backfilling the opening with polysilicon to form the floating gate electrode; and,
isotropically etching the upper portion of the floating gate electrode to form a recessed area.

2. The method of claim 1, further comprising the steps of:
removing the nitride mask layer;
forming a dielectric insulating layer over the floating gate electrode; and,
forming a wordline adjacent and overlying an upper portion of the floating gate electrode.

3. The method of claim 1, wherein the step of isotropically etching comprises a fluorocarbon etching chemistry.

4. The method of claim 3, wherein the fluorocarbon etching chemistry comprises hexafluoroethane (C₂F₆) and argon.

5. The method of claim 2, further comprising the step of forming a nitride passivation layer over the floating gate electrode prior to the step of forming the dielectric insulating layer.

6. The method of claim 1, wherein the step of backfilling comprises a CVD deposition process followed by a chemical mechanical planarization process.

7. The method of claim 1, wherein the recessed area comprises sidewalls sloping inwardly from the floating gate electrode outer edges at an upper portion toward a bottom portion.

8. The method of claim 7, wherein the recessed area comprises a concave shape.

9. The method of claim 7, wherein the bottom portion is substantially level.

10. A method for forming for forming a flash memory cell with an improved floating gate electrode to improve an erase operation comprising the steps of:
providing a semiconductor substrate active area electrically isolated by STI structures;
forming a gate dielectric over the semiconductors substrate;
forming a nitride mask layer on the gate dielectric and forming an opening in the nitride mask layer defining a floating gate electrode;
backfilling the opening with polysilicon according to a CVD deposition and a CMP process to form the floating gate electrode; and,
isotropically etching the upper portion of the floating gate electrode to form a recessed area comprising inwardly sloping sidewall portions.

11. The method of claim 10, further comprising the steps of:
removing the nitride mask layer;
forming a dielectric insulating layer over the floating gate electrode; and,
forming a wordline adjacent and overlying an upper portion of the floating gate electrode.

12. The method of claim 11, wherein a nitride passivation layer is formed over the floating gate electrode prior to the step of forming the dielectric insulating layer.

13. The method of claim 10, wherein the inwardly sloping sidewalls slope inwardly from the floating gate electrode outer edges at an upper portion toward a bottom portion.

14. A flash memory cell with an improved floating gate electrode comprising:
a semiconductor substrate active area electrically isolated by STI structures;
a gate dielectric on the semiconductors substrate; and,
a floating gate electrode on the gate dielectric comprising an upper portion defined by a recessed area comprising inwardly sloping sidewall portions.

15. The flash memory cell of claim 14, further comprising:
a dielectric insulating layer on the floating gate electrode; and,
a wordline adjacent and overlying an upper portion of the floating gate electrode.

16. The flash memory cell of claim 15, wherein the wordline is substantially about the same distance from the floating gate electrode in the adjacent portion and the overlying upper portion.

17. The flash memory cell of claim 15, further comprising a nitride passivation layer on the floating gate electrode underlying the dielectric insulating layer.

18. The flash memory cell of claim 14, wherein the inwardly sloping sidewalls slope inwardly from the floating gate electrode outer edges at an upper portion toward a bottom portion.

19. The flash memory cell of claim 14, wherein the recessed area comprises a concave shape

20. The flash memory cell of claim 14, wherein the bottom portion of the recessed area is substantially level.
